(19) United States
(12) Patent Application Publication
(10) Pub. No.: US 2025/0062726 A1
(43) Pub. Date: Feb. 20, 2025

(54) SENSOR AMPLIFIER CIRCUIT

(71) Applicant: Murata Manufacturing Co., Ltd., Nagaokakyo-shi (JP)

(72) Inventor: Aritsugu YAJIMA, Nagaokakyo-shi (JP)

(21) Appl. No.: 18/934,576

(22) Filed: Nov. 1, 2024

Related U.S. Application Data
(63) Continuation of application No. PCT/JP2023/013620, filed on Mar. 31, 2023.

(30) Foreign Application Priority Data
May 31, 2022 (JP) 2022-088648

(51) Int. Cl. H03F 1/32; G01R 15/20; H03F 3/45

(52) U.S. Cl. CPC H03F 1/3211; H03F 3/45; G01R 15/20

(57) ABSTRACT

A sensor amplifier circuit includes a differential amplifier circuit and a compensation circuit. The differential amplifier circuit is configured to amplify a difference voltage between a pair of output signals from a sensor circuit and generate an output voltage. The compensation circuit is configured to generate a compensation signal based on the output voltage to compensate for a non-linear distortion of the output voltage. The differential amplifier circuit includes a current feedback instrumentation amplifier (CFIA). The compensation circuit includes one or more operational transconductance amplifiers (OTAs) configured to output one or more electric currents based on the output voltage and outputs a sum of the one or more electric currents from the one or more operational transconductance amplifiers as the compensation signal. The compensation signal from the compensation circuit is input to a current feedback loop in the current feedback instrumentation amplifier.

### CROSS REFERENCE TO RELATED APPLICATIONS

This application is a continuation of International Application No. PCT/JP2023/013620, filed Mar. 31, 2023, which claims priority to Japanese Patent Application No. 2022-088648, filed May 31, 2022, the entire contents of each of which are hereby incorporated by reference.

### TECHNICAL FIELD

The present disclosure relates to a sensor amplifier circuit and, more particularly, relates to a technology for compensating for a sensor output using a bridge circuit.

### BACKGROUND

In some related examples, such as disclosed in Japanese Unexamined Patent Application Publication No. 2003-248017, a sensor system can include a sensor circuit that compensates for a sensor output to improve the signal to noise ratio and thereby improve detection accuracy. The sensor circuit disclosed in Japanese Unexamined Patent Application Publication No. 2003-248017 includes a detection unit (also referred to as pre-amplifier) including sensor elements, a power supply unit (also referred to as sensor application circuit) that supplies power to the detection unit, and an amplification unit (also referred to as main amplifier) that amplifies a signal from the detection unit. The sensor application circuit includes a constant voltage circuit, a sensitivity temperature compensation circuit, and a non-linearity compensation circuit, and the non-linearity compensation circuit is disposed in a feedback circuit for feeding back a sensor circuit output. In the sensor circuit disclosed in Japanese Unexamined Patent Application Publication No. 2003-248017, the non-linearity compensation circuit is used to shift the potential applied from the constant voltage circuit to the pre-amplifier and thereby improve the linearity of the sensor circuit.

### SUMMARY

As a sensor circuit using sensor elements configured as a bridge circuit, there is, for example, a magnetic sensor using a tunneling magneto-resistive (TMR) element. In some exemplary aspect, such a magnetic sensor is used as a current sensor in an electric-powered vehicle, such as an electric vehicle (EV) or a hybrid vehicle (HV). In such an application, in addition to highly accurate sensor outputs, high-speed responsiveness is required from the perspective of the operability of a vehicle and safety.

According to the sensor circuit disclosed in Japanese Unexamined Patent Application Publication No. 2003-248017, the accuracy can be improved by the sensitivity temperature compensation circuit and the non-linearity compensation circuit. However, because the non-linearity compensation circuit is formed in the voltage feedback circuit for feeding back a sensor circuit output and the sensor circuit output is fed back to the input side of the pre-amplifier, there is an inevitable delay in the circuit responsiveness, and it is possible that required responsiveness cannot be achieved.

In view of the foregoing, the present disclosure has been made to solve the above problem according to an exemplary aspect. Thus, it is an object of the present disclosure to improve the linearity of an amplifier circuit for a sensor implemented by a bridge circuit while achieving high responsiveness.

In an exemplary aspect, a sensor amplifier circuit is provided that amplifies an output of a sensor circuit including four sensor elements that are connected to each other in a bridge configuration. The sensor amplifier circuit includes a differential amplifier circuit that amplifies a difference voltage between a pair of output signals from the sensor circuit, and a compensation circuit that, based on an output voltage of the differential amplifier circuit, generates a compensation signal to compensate for non-linear distortion of the output voltage. The differential amplifier circuit is implemented by a current feedback instrumentation amplifier (CFIA). Moreover, the compensation circuit includes at least one operational transconductance amplifier (OTA) configured to output an electric current corresponding to the output voltage and outputs a sum of one or more output currents from the at least one operational transconductance amplifier as the compensation signal. The compensation signal from the compensation circuit is input to a current feedback loop in the current feedback instrumentation amplifier.

In the sensor amplifier circuit according to the present disclosure, the differential amplifier circuit can be implemented by a current feedback instrumentation amplifier (CFIA), and a compensation signal, which compensates for non-linear distortion and is generated by the compensation circuit including the operational transconductance amplifier (OTA), is fed back to the current feedback loop of the CFIA circuit. With this configuration, because an intermediate signal (e.g., current signal) in the differential amplifier circuit is fed back, the fed-back signal does not pass through the input-stage amplifier (e.g., an operational amplifier). This configuration improves responsiveness compared with a voltage feedback compensation circuit in some related examples, such as those described above. Therefore, linearity is also improved while achieving high responsiveness.

According to an exemplary aspect, a sensor amplifier circuit includes a differential amplifier circuit and a compensation circuit. The differential amplifier circuit is configured to amplify a difference voltage between a pair of output signals from a sensor circuit to generate an output voltage. The compensation circuit is configured to generate a compensation signal based on the output voltage to compensate for a non-linear distortion of the output voltage. The differential amplifier circuit includes a current feedback instrumentation amplifier (CFIA). The compensation circuit includes one or more operational transconductance amplifiers (OTAs) configured to output one or more electric currents based on the output voltage and outputs a sum of the one or more electric currents from the one or more operational transconductance amplifiers as the compensation signal. The compensation signal from the compensation circuit is input to a current feedback loop in the current feedback instrumentation amplifier.

According to another exemplary aspect, a sensor amplifier circuit includes a differential amplifier circuit with a current feedback loop. The differential amplifier circuit is configured to amplify a difference voltage from a sensor circuit and generate an output voltage in response to the difference voltage. The sensor amplifier circuit also includes a compensation circuit configured to generate a compensation current signal based on the output voltage, the compensation current signal is input to the current feedback loop that compensates for a non-linear distortion of the output voltage.

### BRIEF DESCRIPTION OF DRAWINGS

FIG. 1 is a schematic diagram of a sensor system using a sensor amplifier circuit according to a first exemplary embodiment.

FIG. 2 is a first diagram for describing the outline of linearity compensation in the sensor amplifier circuit.

FIG. 3 is a second diagram for describing the outline of linearity compensation in the sensor amplifier circuit.

FIG. 4 is an equivalent model for calculating a transfer function of the sensor amplifier circuit.

FIG. 5 is a diagram showing outputs of the sensor amplifier circuit observed when the reference voltage of a linearity compensation circuit is varied in the equivalent model of FIG. 4.

FIG. 6 is a schematic diagram of a sensor system using a sensor amplifier circuit according to a second exemplary embodiment.

FIG. 7 is a diagram for describing the outline of the temporal variation of a compensation signal observed when filter circuits are provided.

FIG. 8 is a schematic diagram of a sensor system using a sensor amplifier circuit according to a third exemplary embodiment.

### DETAILED DESCRIPTION OF EMBODIMENTS

Exemplary embodiments of the present disclosure are described in detail below with reference to the drawings. The same reference number is assigned to the same or similar components in the drawings, and the descriptions of those components are not repeated.

### First Exemplary Embodiment

### (Overview of Sensor System)

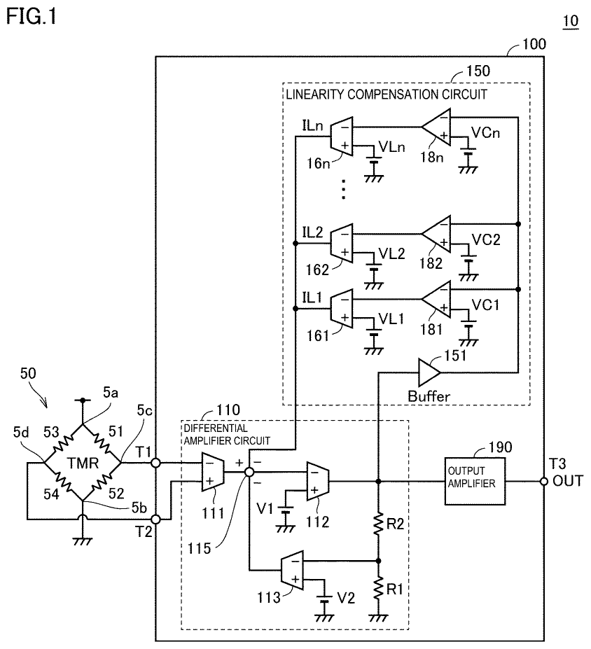

FIG. 1 is a schematic diagram of a sensor system 10 using a sensor amplifier circuit 100 according to a first exemplary embodiment. Referring to FIG. 1, the sensor system 10 includes a sensor circuit 50 and a sensor amplifier circuit 100.

As shown, the sensor circuit 50 includes four sensor elements 51 to 54 that are connected to each other in a bridge configuration. In the example of FIG. 1, each of the sensor elements 51 to 54 is a tunneling magneto-resistive (TMR) element, which is a magnetic sensor whose resistance value varies according to a detected magnetic field. Also, in some exemplary aspect, each of the sensor elements 51 to 54 is implemented by any other type of resistor element whose resistance value varies according to a detected physical quantity.

The sensor elements 51 and 52 are connected in series between a pair of supply terminals 5a and 5b. Also, the sensor elements 53 and 54 are connected in series between the pair of supply terminals 5a and 5b. The sensor circuit 50 operates when a predetermined voltage is applied to the supply terminals 5a and 5b, and according to a detected magnetic field, generates a voltage difference between a pair of signal output terminals 5c and 5d. The signal output terminal 5c is a connection node between the sensor elements 51 and 52, and the signal output terminal 5d is a connection node between the sensor elements 53 and 54.

The signal output terminals 5c and 5d are connected to input terminals T1 and T2 of the sensor amplifier circuit 100, respectively. That is, the difference voltage between the pair of output signals of the sensor circuit 50 is given as an input to the sensor amplifier circuit 100.

In addition to the input terminals T1 and T2, the sensor amplifier circuit 100 includes an output terminal T3, a differential amplifier circuit 110, a linearity compensation circuit 150, and an output amplifier 190. The sensor amplifier circuit 100 amplifies output signals received from the sensor circuit 50 via the input terminals T1 and T2 by using the differential amplifier circuit 110 and the output amplifier 190, and outputs the amplified signal from the output terminal T3. Also, while the output signal is amplified by the differential amplifier circuit 110, the sensor amplifier circuit 100 compensates for non-linear distortion generated in the sensor circuit 50 by using the linearity compensation circuit 150.

According to an exemplary aspect, the differential amplifier circuit 110 can be implemented by a so-called current feedback instrumentation amplifier (CFIA) and includes amplifiers 111 to 113, reference voltages V1 and V2, a subtractor 115, and resistors R1 and R2.

Each of the amplifiers 111 to 113 can be implemented by an operational transconductance amplifier (OTA) that outputs, from its output terminal, an electric current corresponding to the potential difference input to its inverting input terminal and its non-inverting input terminal. The inverting input terminal and the non-inverting input terminal of the input stage amplifier 111 are connected, respectively, to the input terminals T1 and T2, and output signals from the sensor circuit 50 are input to the inverting input terminal and the non-inverting input terminal. The output terminal of the amplifier 111 is connected to the inverting input terminal of the output stage amplifier 112 via the subtractor 115.

The reference voltage V1 is connected to the non-inverting input terminal of the amplifier 112. The amplifier 112 outputs, from the output terminal, an electric current corresponding to the difference voltage between an output signal from the amplifier 111 and the reference voltage V1. Here, because the input terminal of the amplifier 112 has predetermined impedance, a current signal output from the amplifier 111 is converted into a voltage signal by the impedance, and the voltage signal is input to the amplifier 112. The resistors R1 and R2 are connected in series between the output terminal of the amplifier 112 and the ground potential. A current signal output from the amplifier 112 is converted into a voltage signal by the resistors R1 and R2, and the voltage signal is input to the output amplifier 190. In some exemplary aspects, the output amplifier 190 can be implemented by any type of amplifier circuit that amplifies an output signal from the differential amplifier circuit 110 and outputs the amplified signal to an external device via the output terminal T3.

The connection node between the resistor R1 and the resistor R2 is connected to the inverting input terminal of the amplifier 113. The resistors R1 and R2 also function as voltage dividing resistors, and a signal obtained by dividing the voltage of the output signal from the amplifier 112 is input to the inverting input terminal of the amplifier 113. The reference voltage V2 is connected to the non-inverting input terminal of the amplifier 113. The amplifier 113 outputs, from the output terminal, an electric current corresponding to the difference voltage between the voltage-divided output signal of the amplifier 112 and the reference voltage V2. The output terminal of the amplifier 113 is connected to the subtractor 115. A current feedback loop of the CFIA is formed by the amplifier 113.

As further shown, the linearity compensation circuit 150 includes a buffer 151, multiple operational transconductance amplifiers (OTAs) 161 to 16n, and comparison circuits 181 to 18n. In the descriptions below and for purposes of this disclosure, the operational transconductance amplifiers 161 to 16n are collectively referred to as “operational transconductance amplifiers 160” according to an exemplary aspect, and the comparison circuits 181 to 18n are collectively referred to as “comparison circuits 180” according to an exemplary aspect. It should be appreciated that the linearity compensation circuit 150 does not necessarily include multiple operational transconductance amplifiers and can include at least one operational transconductance amplifier.

The operational transconductance amplifiers 161 to 16n are connected in parallel between the input terminal and the output terminal of the linearity compensation circuit 150. An output signal from the differential amplifier circuit 110 is supplied to the inverting input terminals of the operational transconductance amplifiers 161 to 16n via the buffer 151 and the corresponding comparison circuits 181 to 18n. Also, reference voltages VL1 to VLn are connected to the non-inverting input terminals of the corresponding operational transconductance amplifiers 161 to 16n. The output terminals of the operational transconductance amplifiers 161 to 16n are connected to the subtractor 115, which is the current feedback loop in the differential amplifier circuit 110.

The output terminal of the buffer 151 is connected to the inverting terminal of each of the comparison circuits 181 to 18n. Reference voltages VC1 to VCn are connected to the non-inverting terminals of the corresponding comparison circuits 181 to 18n. Each of the comparison circuits 181 to 18n outputs a predetermined voltage when the output voltage of the differential amplifier circuit 110 exceeds the corresponding reference voltage. By setting the reference voltages VC1 to VCn to different values, compensation points in the linearity compensation circuit 150 can be set as the output voltage of the differential amplifier circuit 110 increases.

Each of the operational transconductance amplifiers 161 to 16n outputs a predetermined electric current when the output voltage of the corresponding comparison circuit exceeds the corresponding one of the reference voltages VL1 to VLn that are set individually. With the combinations of the comparison circuits 181 to 18n and the operational transconductance amplifiers 161 to 16n, the output current from the linearity compensation circuit 150 gradually increases as the output voltage of the differential amplifier circuit 110 increases.

The reference voltages VL1 to VLn of the operational transconductance amplifiers 161 to 16n are for adjusting the output timing of output currents at compensation points determined by the comparison circuits 181 to 18n. However, the reference voltages VL1 to VLn are set to zero according to an exemplary aspect.

In operation of the differential amplifier circuit 110, the input current to the amplifier 112 decreases as the output current from the linearity compensation circuit 150 increases, and as a result, the output voltage decreases. In the sensor amplifier circuit 100 of the first embodiment, the feedback signal of the linearity compensation circuit 150 is input to the current loop on the output side of the amplifier 111 rather than to the input side of the input stage amplifier 111. That is, the compensation performed by the linearity compensation circuit 150 is not to change the gain (i.e., the inclination of the output signal) of the differential amplifier circuit 110 but to offset the output signal. This configuration suppresses a sudden change in an output signal at a compensation timing, which tends to occur when the gain is changed, and thereby causes the output signal to change gradually as a result of compensation and to also reduce the discontinuity of an output waveform.

Because feedback control is used for compensation, the compensation operation can be continued without causing oscillation even when, for example, the sensor signal successively and repeatedly increases and decreases at a compensation point, that is, when, for example, signals straddling the reference voltage VL1 are successively input to the operational transconductance amplifier 161 in FIG. 1. Also, because feedback is made by the current feedback loop at the midpoint of the differential amplifier circuit, the influence of the feedback on the response time can be reduced compared with a case in which feedback is made to the input stage of a circuit.

### (Description of Linearity Compensation)

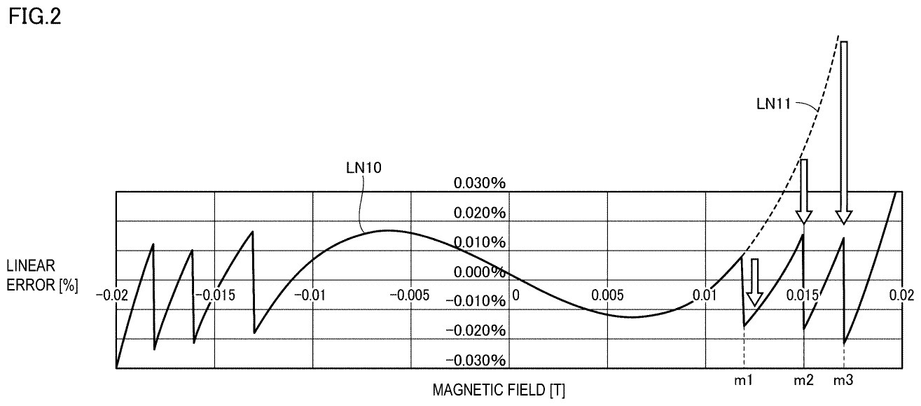

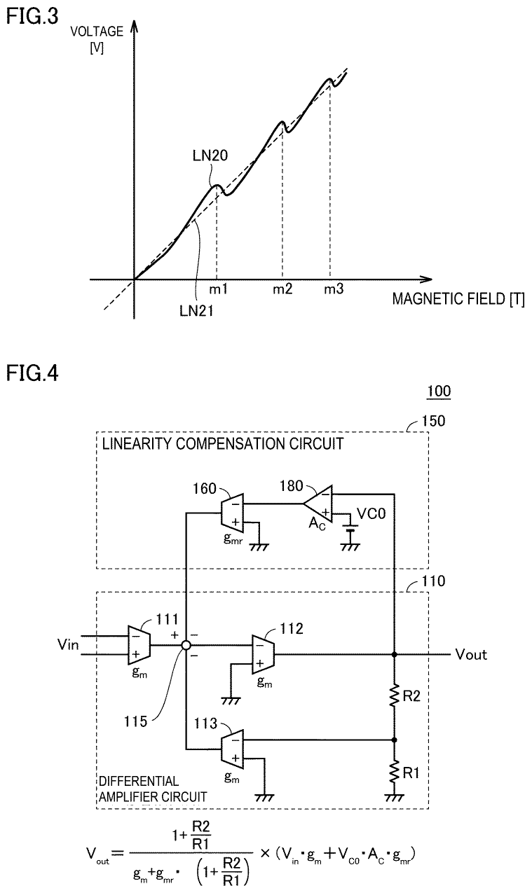

Next, with reference to FIGS. 2 and 3, linearity compensation in the sensor amplifier circuit 100 is described. FIG. 2 is a diagram showing a simulation result of error distortion in the sensor circuit 50 from the ideal straight line of a sensor output signal with respect to the magnetic field. Also, FIG. 3 is a diagram showing the output voltage of the sensor amplifier circuit 100 with respect to the magnetic field when linearity compensation is employed.

Referring to FIG. 2, the variation of the output signal from the sensor circuit 50 with respect to the magnetic field may include, in addition to proportional straight line components, an error distortion component like a cubic function as indicated by a dotted line LN11. Therefore, when an output signal from the sensor circuit 50 is used without applying linearity compensation to the output signal, the error gradually increases as the magnitude (i.e., an absolute value) of the magnetic field increases.

In the linearity compensation circuit 150 of the first embodiment, as described above, each time the output voltage of the differential amplifier circuit 110 reaches a predetermined reference voltage set for each operational transconductance amplifier 160, a predetermined compensation current is output from the operational transconductance amplifier, and the output voltage is thereby offset in a direction to decrease the output voltage.

In FIG. 2, when the magnetic field reaches each of m1, m2, and m3, an offset is applied in a direction to reduce the error. As a result of performing linearity compensation, the linear error is almost within +0.02% throughout the entire detection range.

Here, the change rate (i.e., inclination) in a section between m1 and m2 is the same as the inclination of the dotted line LN11 in the same section. Similarly, the inclination in a section between m2 and m3 is the same as the inclination of the dotted line LN11 in the same section. In other words, with the compensation performed by the linearity compensation circuit 150, the gain does not change depending on whether the compensation is performed. Therefore, a smoother change can be obtained compared with compensation by gain switching.

As shown in FIG. 3, the output voltage from the sensor amplifier circuit 100 behaves as indicated by a solid line LN20 in contrast to the ideal linear output (dotted line LN21). That is, when the magnetic field reaches each of m1, m2, and m3, i.e., when the difference between the output voltage (solid line LN20) and the linear output (dotted line LN21) exceeds a predetermined value, the output voltage is reduced by linearity compensation. As a result, as shown in FIG. 3, the output voltage (solid line LN20) changes to follow the ideal linear output (dotted line LN21).

According to an exemplary aspect, to improve the sensor detection accuracy by linearity compensation, it is necessary to more finely perform compensation by setting many compensation points. In this case, however, it is necessary to increase the number of operational transconductance amplifiers 160 in the linearity compensation circuit 150. This in turn increases the circuit size and may hinder the miniaturization of the entire device. Therefore, the number of operational transconductance amplifiers 160 is appropriately determined taking into account the required sensor detection accuracy and the allowable size of the sensor amplifier circuit 100.

FIG. 4 is an equivalent model for calculating a transfer function of the sensor amplifier circuit 100. In the model illustrated in FIG. 4, for ease of explanation, the linearity compensation circuit 150 includes one operational transconductance amplifier 160. Also, in FIG. 4, the transconductance of each of the amplifiers 111 to 113 in the differential amplifier circuit 110 is represented by gₘ, and the transconductance of the operational transconductance amplifier 160 in the linearity compensation circuit 150 is represented by gₘᵣ. Furthermore, the gain of the comparison circuit 180 in the linearity compensation circuit 150 is represented by A_{c}. In the model of FIG. 4, the reference voltage of the operational transconductance amplifier 160 of the linearity compensation circuit 150 and the reference voltages V1 and V2 of the amplifiers 112 and 113 of the differential amplifier circuit 110 are set to zero.

The transfer function of the model illustrated in FIG. 4 is represented by formula (1) below.

$$[ formula ( 1 ) ]$$

$${V}_{out} = \frac{1 + \frac{R 2}{R 1}}{{g}_{m} + {g}_{mr} \cdot ( 1 + \frac{R 2}{R 1} )} \times ( {V}_{in} \cdot {g}_{m} + {V}_{LO} \cdot {g}_{mr} ) \qquad ( 1 )$$

In formula (1), (Vᵢₙ·gₘ) is a term representing an input voltage from the sensor circuit 50, and (V_{C0}·A_{C}·gₘᵣ) is a term representing a compensation voltage from the linearity compensation circuit 150. As shown in formula (1), because the transconductance gₘᵣ of the operational transconductance amplifier 160 in the linearity compensation circuit 150 is included as a common term, the transconductance gₘᵣ actually also influences a gain Gᵢₙ represented by an input voltage term (i.e., the differential amplifier circuit 110) shown in formula (2).

$$[ formula ( 2 ) ]$$

$${G}_{in} = \frac{1 + \frac{R 2}{R 1}}{1 + \frac{{g}_{mr}}{{g}_{m}} \cdot ( 1 + \frac{R 2}{R 1} )} \qquad ( 2 )$$

As is shown from formula (2), to reduce the influence of the linearity compensation circuit 150 on the gain Gᵢₙ, according to an exemplary aspect, it is set the transconductance gₘᵣ of the linearity compensation circuit 150 as small as possible with respect to the transconductance gₘ of the differential amplifier circuit 110 (gₘᵣ<<gₘ).

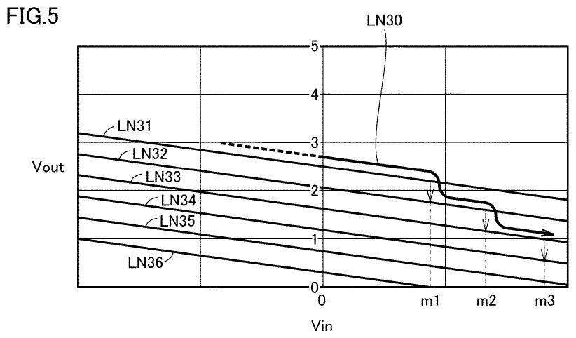

FIG. 5 shows simulation results of the variation in an output voltage Vₒᵤₜ with respect to an input voltage Vᵢₙ that are obtained by using the model illustrated in FIG. 4 and changing the compensation current output from the operational transconductance amplifier 160. In FIG. 5, the compensation current output from the operational transconductance amplifier 160 is smallest in the case of a line LN31, and the compensation current output from the operational transconductance amplifier 160 increases toward a line LN36.

As shown in FIG. 5, the ratio of the output voltage Vₒᵤₜ with respect to the input voltage Vᵢₙ, i.e., the inclination, remains approximately the same even when the compensation current output from the operational transconductance amplifier 160 is changed. In other words, when the compensation current output from the operational transconductance amplifier 160 is increased, the output voltage Vₒᵤₜ is offset in a decreasing direction.

In the first embodiment, as the magnitude of the detected magnetic field increases and reaches each of m1, m2, and m3, the compensation current output from the operational transconductance amplifier 160 is increased. As a result, conceptually, the output voltage Vₒᵤₜ decreases stepwise as indicated by a line LN30 in FIG. 5. However, because the input voltage Vᵢₙ itself exhibits non-linear behavior like a cubic function as described with reference to FIG. 2, the linearity is improved by feeding back a compensation current such that the output voltage Vout decreases stepwise as shown in FIG. 5.

As described above, compared with a voltage feedback compensation circuit, with a configuration in which the differential amplifier circuit 110 is implemented by a current feedback instrumentation amplifier (CFIA) and the linearity compensation circuit 150 implemented by operational transconductance amplifiers (OTA) is used to feed back a compensation current corresponding to an output voltage to the current feedback loop of the differential amplifier circuit 110, it is possible to improve the linearity of the output signal while achieving high responsiveness.

For purposes of this disclosure, it is noted that “amplifiers 111, 112, and 113” in the first exemplary embodiment correspond, respectively, to “first amplifier”, “second amplifier”, and “third amplifier” in the present disclosure. “Resistors R1 and R2” in the first exemplary embodiment correspond to “voltage dividing resistors” in the present disclosure.

### Second Exemplary Embodiment

In a second embodiment, a configuration in which a linearity compensation circuit includes filter circuits is described.

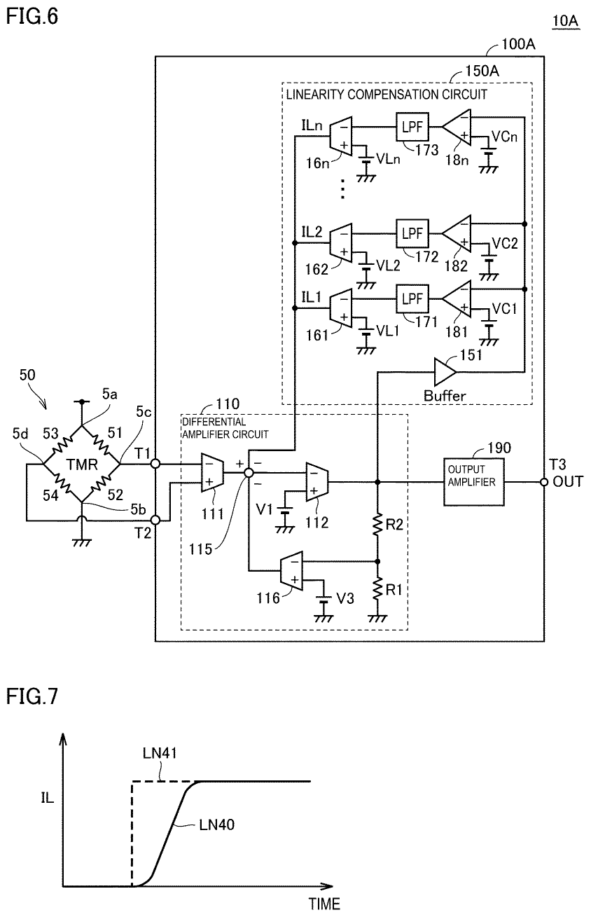

FIG. 6 is a schematic diagram of a sensor system 10A using a sensor amplifier circuit 100A according to the second embodiment. In the sensor amplifier circuit 100A, the linearity compensation circuit 150 in the first embodiment is replaced with a linearity compensation circuit 150A. Other components of the sensor amplifier circuit 100A are the same as the corresponding components of the sensor amplifier circuit 100, and the descriptions of those components are not repeated.

Referring to FIG. 6, in the linearity compensation circuit 150A, low pass filters (LPF) 171 to 17n are connected to the inverting input terminals of the corresponding operational transconductance amplifiers 161 to 16n. That is, output voltages of the comparison circuits 181 to 18n are supplied to the operational transconductance amplifier 161 to 16n via the corresponding low pass filters 171 to 17n. With the low pass filters provided, signals input to the operational transconductance amplifiers 161 to 16n change gradually. Accordingly, as shown in FIG. 7, a compensation current IL output from the operational transconductance amplifier 160 also changes more gradually (solid line LN40) compared with a case in which low pass filters are not provided (dotted line LN41).

With the above configuration, although the responsiveness of the feedback loop slightly decreases, an abrupt change in the compensation current is suppressed. This configuration in turn suppresses the variation in the output voltage when a compensation current is added at each compensation point and thereby further improves the linearity.

Here, in the configuration illustrated in FIG. 6, the low pass filters are connected to the inverting input terminals of the operational transconductance amplifiers 161 to 16n. In some exemplary aspects, the low pass filters are connected to the output terminals of the operational transconductance amplifiers 161 to 16n. As still another example, one common low pass filter is provided on the output terminal side of the operational transconductance amplifiers 161 to 16n.

### Third Exemplary Embodiment

According to a third exemplary embodiment, in the linearity compensation circuit, the reference voltages for the operational transconductance amplifiers are removed, and voltage dividing circuits are added.

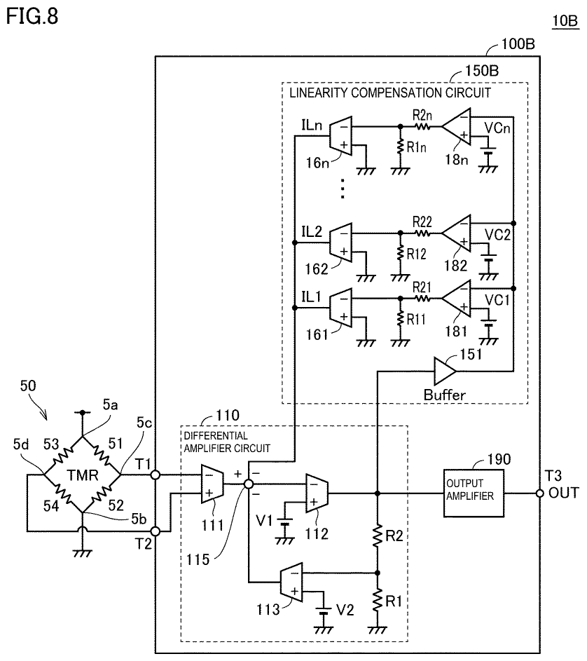

FIG. 8 is a schematic diagram of a sensor system 10B using a sensor amplifier circuit 100B according to the third embodiment. In the sensor amplifier circuit 100B, the linearity compensation circuit 150 in the first exemplary embodiment is replaced with a linearity compensation circuit 150B. Other components of the sensor amplifier circuit 100B are the same as the corresponding components of the sensor amplifier circuit 100, and the descriptions of those components are not repeated.

Referring to FIG. 8, in the linearity compensation circuit 150B, a voltage dividing circuit is connected between the inverting input terminal of each of the operational transconductance amplifiers 161 to 16n and the corresponding one of the comparison circuits 181 to 18n. Each voltage dividing circuit is comprised of two series-connected resistors (each pair of resistors R11 to R1n and resistors R21 through R2n). One end of each of the resistors R21 to R2n is connected to the output terminal of the corresponding one of the comparison circuits 181 to 18n, and the other end of each of the resistors R21 to R2n is connected to the ground potential via the corresponding one of the resistors R11 to R1n. The connection node between each pair of the resistors R21 to R2n and the resistors R11 to R1n is connected to the inverting input terminal of the corresponding one of the operational transconductance amplifiers 161 to 16n.

In the linearity compensation circuit 150 of the first embodiment, the reference voltages VL1 to VLn are provided for the respective operational transconductance amplifiers 161 to 16n. However, as the number of operational transconductance amplifiers increases, the number of reference voltages increases, and the number of circuits for outputting the reference voltages increases. This configuration in turn increases the area of an IC substrate on which a sensor amplifier circuit is formed and may also increase the size of an entire device including the sensor amplifier circuit. On the other hand, when the reference voltage is reduced and fixed at 0 V, the flexibility in selecting an output current is reduced, and it may become difficult to sufficiently improve the linearity of the output voltage.

In the linearity compensation circuit 150B of the third embodiment, because a voltage dividing circuit comprised of resistors is formed at the inverting input terminal of each of the operational transconductance amplifiers 161 to 16n, input voltages to the operational transconductance amplifiers 161 to 16n can be individually adjusted using a small substrate area. This configuration improves the linearity of the output voltage while suppressing an increase in the size of a sensor amplifier circuit.

Also, according to some exemplary aspects, the low pass filter described in the second embodiment is added after each voltage dividing circuit.

### Aspects

(Paragraph 1) A sensor amplifier circuit according to an exemplary aspect amplifies an output of a sensor circuit including four sensor elements that are connected to each other in a bridge configuration. The sensor amplifier circuit includes a differential amplifier circuit that amplifies a difference voltage between a pair of output signals from the sensor circuit and a compensation circuit that, based on an output voltage of the differential amplifier circuit, generates a compensation signal to compensate for non-linear distortion of the output voltage. The differential amplifier circuit is implemented by a current feedback instrumentation amplifier (CFIA). The compensation circuit includes at least one operational transconductance amplifier (OTA) configured to output an electric current corresponding to the output voltage and outputs a sum of one or more output currents from the at least one operational transconductance amplifier as the compensation signal. The compensation signal from the compensation circuit is input to a current feedback loop in the current feedback instrumentation amplifier.

(Paragraph 2) In the sensor amplifier circuit according to paragraph 1, the compensation circuit further includes a comparison circuit that sets a compensation point for the at least one operational transconductance amplifier according to the output voltage.

(Paragraph 3) In the sensor amplifier circuit according to paragraph 2, the compensation circuit further includes a filter circuit that filters an output of the comparison circuit and supplies the filtered output to the at least one operational transconductance amplifier.

(Paragraph 4) In the sensor amplifier circuit according to paragraph 3, the filter circuit is a low pass filter.

(Paragraph 5) In the sensor amplifier circuit according to paragraph 4, the compensation circuit includes multiple operational transconductance amplifiers. The filter circuit is provided for each of the multiple operational transconductance amplifiers.

(Paragraph 6) In the sensor amplifier circuit according to any one of paragraphs 2 to 4, the compensation circuit further includes a voltage dividing circuit that divides the voltage of an output of the comparison circuit to obtain a divided voltage output and supplies the divided voltage output to the at least one operational transconductance amplifier.

(Paragraph 7) In the sensor amplifier circuit according to paragraph 6, the compensation circuit includes multiple operational transconductance amplifiers. The voltage dividing circuit is provided for each of the multiple operational transconductance amplifiers.

(Paragraph 8) In the sensor amplifier circuit according to any one of paragraphs 1 to 7, the compensation circuit includes a first operational transconductance amplifier and a second operational transconductance amplifier. The first operational transconductance amplifier outputs a first compensation current when the output voltage reaches a first threshold. The second operational transconductance amplifier outputs a second compensation current when the output voltage reaches a second threshold greater than the first threshold.

(Paragraph 9) In the sensor amplifier circuit according to any one of paragraphs 1 to 7, the current feedback instrumentation amplifier includes first, second, and third amplifiers, each of which is implemented by an operational transconductance amplifier (OTA), a subtractor, and voltage dividing resistors. Each of the first, second, and third amplifiers includes an inverting input terminal, a non-inverting input terminal, and an output terminal. The pair of output signals from the sensor circuit include a first signal and a second signal. The first signal is input to the inverting input terminal of the first amplifier. The second signal is input to the non-inverting input terminal of the first amplifier. The output terminal of the first amplifier is connected to the inverting input terminal of the second amplifier via the subtractor. A first reference voltage is connected to the non-inverting input terminal of the second amplifier. The output terminal of the second amplifier is connected to the inverting input terminal of the third amplifier via the voltage dividing resistors. A second reference voltage is connected to the non-inverting input terminal of the third amplifier. The output terminal of the third amplifier is connected to the subtractor. An output of the compensation circuit is connected to the subtractor.

In general, it is noted that the above-disclosed exemplary embodiments are considered as examples and not restrictive in all respects.

### REFERENCE SIGNS LIST

5a, 5b supply terminal; 5c, 5d signal output terminal; 10, 10A, 10B sensor system; 50 sensor circuit; 51, 52, 53, 54 sensor element; 100, 100A, 100B sensor amplifier circuit; 110 differential amplifier circuit; 111, 112, 113 amplifier; 115 subtractor; 150, 150A, 150B linearity compensation circuit; 151 buffer; 160 to 16n operational transconductance amplifier; 171 to 17n filter circuit; 181 to 18n comparison circuit; 190 output amplifier; R1, R2, R11 to R1n, R21 to R2n resistor; T1, T2 input terminal; T3 output terminal; V1, V2, VC0 to VCn, VL0 to VLn reference voltage

What is claimed is:

1. A sensor amplifier circuit, comprising:
a differential amplifier circuit configured to amplify a difference voltage between a pair of output signals from a sensor circuit to generate an output voltage; and
a compensation circuit configured to generate a compensation signal based on the output voltage to compensate for a non-linear distortion of the output voltage, wherein:
the differential amplifier circuit includes a current feedback instrumentation amplifier (CFIA);
the compensation circuit includes one or more operational transconductance amplifiers (OTAs) configured to output one or more electric currents based on the output voltage and output a sum of the one or more electric currents from the one or more OTAs as the compensation signal; and
the compensation signal from the compensation circuit is input to a current feedback loop in the current feedback instrumentation amplifier.

2. The sensor amplifier circuit according to claim 1, wherein the compensation circuit further includes a comparison circuit configured to set a compensation point for a first operational transconductance amplifier in the one or more operational transconductance amplifiers according to the output voltage.

3. The sensor amplifier circuit according to claim 2, wherein the compensation circuit further includes a filter circuit configured to filter an output of the comparison circuit to generate a filtered output and to supply the filtered output to the first operational transconductance amplifier.

4. The sensor amplifier circuit according to claim 3, wherein the filter circuit is a low pass filter.

5. The sensor amplifier circuit according to claim 4, wherein:
the compensation circuit includes a plurality of operational transconductance amplifiers; and
the filter circuit is provided for each of the plurality of operational transconductance amplifiers.

6. The sensor amplifier circuit according to claim 2, wherein the compensation circuit further includes a voltage dividing circuit configured to divide a comparison output voltage of the comparison circuit to obtain a divided voltage output and to supply the divided voltage output to the first operational transconductance amplifier.

7. The sensor amplifier circuit according to claim 6, wherein:
the compensation circuit includes a plurality of operational transconductance amplifiers; and
the voltage dividing circuit is provided for each of the plurality of operational transconductance amplifiers.

8. The sensor amplifier circuit according to claim 1, wherein:
the compensation circuit includes a first operational transconductance amplifier and a second operational transconductance amplifier;
the first operational transconductance amplifier is configured to output a first compensation current when the output voltage reaches a first threshold; and
the second operational transconductance amplifier is configured to output a second compensation current when the output voltage reaches a second threshold greater than the first threshold.

9. The sensor amplifier circuit according to claim 1, wherein:
the current feedback instrumentation amplifier includes a first amplifier, a second amplifier, a third amplifier, a subtractor, and voltage dividing resistors, each of the first amplifier, the second amplifier and the third amplifier being implemented by an operational transconductance amplifier (OTA);
each of the first amplifier, the second amplifier, and the third amplifier includes an inverting input terminal, a non-inverting input terminal, and an output terminal;
the pair of output signals from the sensor circuit include a first signal and a second signal;
the first signal is input to the inverting input terminal of the first amplifier;
the second signal is input to the non-inverting input terminal of the first amplifier;
the output terminal of the first amplifier is connected to the inverting input terminal of the second amplifier via the subtractor;
a first reference voltage is connected to the non-inverting input terminal of the second amplifier;
the output terminal of the second amplifier is connected to the inverting input terminal of the third amplifier via the voltage dividing resistors;
a second reference voltage is connected to the non-inverting input terminal of the third amplifier;
the output terminal of the third amplifier is connected to the subtractor; and
an output of the compensation circuit is connected to the subtractor.

10. A sensor amplifier circuit, comprising:
a differential amplifier circuit with a current feedback loop, the differential amplifier circuit being configured to amplify a difference voltage from a sensor circuit and to generate an output voltage in response to the difference voltage; and
a compensation circuit configured to generate a compensation current signal based on the output voltage, the compensation current signal being input to the current feedback loop that compensates for a non-linear distortion of the output voltage.

11. The sensor amplifier circuit according to claim 10, wherein the compensation circuit includes at least a first operational transconductance amplifier (OTA) configured to output a first electric current based on the output voltage, the first electric current being at least a portion of the compensation current signal that is input to the current feedback loop.

12. The sensor amplifier circuit according to claim 11, wherein the compensation circuit further includes a first comparison circuit that is configured to set a compensation point for the first operational transconductance amplifier.

13. The sensor amplifier circuit according to claim 12, wherein the compensation circuit further includes a first filter circuit configured to filter an output of the first comparison circuit to generate a first filtered output and to supply the first filtered output to the first operational transconductance amplifier.

14. The sensor amplifier circuit according to claim 13, wherein the first filter circuit is a low pass filter.

15. The sensor amplifier circuit according to claim 10, wherein the compensation circuit includes a plurality of operational transconductance amplifiers (OTAs) configured to output a plurality of electric currents based on the output voltage and to output a sum of the plurality of electric currents from the plurality of operational transconductance amplifiers as the compensation current signal.

16. The sensor amplifier circuit according to claim 15, wherein the compensation circuit further includes a plurality of comparison circuits that respectively set compensation points for the plurality of operational transconductance amplifiers, the compensation points being different for the plurality of operational transconductance amplifiers.

17. The sensor amplifier circuit according to claim 16, wherein the compensation circuit further includes a plurality of voltage dividing circuits that respectively divide a plurality of comparison output voltages of the plurality of comparison circuits to obtain a plurality of divided voltage outputs that are respectively supplied to the plurality of operational transconductance amplifiers.

18. The sensor amplifier circuit according to claim 10, wherein:
the compensation circuit includes a first operational transconductance amplifier and a second operational transconductance amplifier;
the first operational transconductance amplifier configured to output a first compensation current when the output voltage reaches a first threshold; and
the second operational transconductance amplifier configured to output a second compensation current when the output voltage reaches a second threshold greater than the first threshold.

19. The sensor amplifier circuit according to claim 10, wherein the differential amplifier circuit includes a current feedback instrumentation amplifier.

20. The sensor amplifier circuit according to claim 19, wherein:
the current feedback instrumentation amplifier includes a first amplifier, a second amplifier, a third amplifier, a subtractor, and voltage dividing resistors;
each of the first amplifier, the second amplifier and the third amplifier is implemented by an operational transconductance amplifier (OTA);
each of the first amplifier, the second amplifier and the third amplifier includes an inverting input terminal, a non-inverting input terminal, and an output terminal;
a pair of output signals from the sensor circuit include a first signal and a second signal;
the first signal is input to the inverting input terminal of the first amplifier;
the second signal is input to the non-inverting input terminal of the first amplifier;
the output terminal of the first amplifier is connected to the inverting input terminal of the second amplifier via the subtractor;
a first reference voltage is connected to the non-inverting input terminal of the second amplifier;
the output terminal of the second amplifier is connected to the inverting input terminal of the third amplifier via the voltage dividing resistors;
a second reference voltage is connected to the non-inverting input terminal of the third amplifier;
the output terminal of the third amplifier is connected to the subtractor; and
an output of the compensation circuit is connected to the subtractor.
